(19) United States
(12) Patent Application Publication
(10) Pub. No.: US 2009/0166743 A1
(43) Pub. Date: Jul. 2, 2009

(54) INDEPENDENT GATE ELECTRODES TO INCREASE READ STABILITY IN MULTI-GATE TRANSISTORS

(76) Inventors: Ravi Pillarisetty, Portland, OR (US); Brian S. Doyle, Portland, OR (US); Jack T. Kavalieros, Portland, OR (US); Robert S. Chau, Beaverton, OR (US)

Correspondence Address: COOL PATENT, P.C.;c/o CPA Global, P.O. BOX 52050, MINNEAPOLIS, MN, 55402, US

(21) Appl. No.: 11/964,633

(22) Filed: Dec. 26, 2007

(51) Int. Cl. H01L 29/78; H01L 21/28

(52) U.S. Cl. 257/365; 438/588; 257/E29.264; 257/E21.177

(57) ABSTRACT

Independent gate electrodes for multi-gate transistors are generally described. In one example, an apparatus includes a semiconductor fin, one or more multi-gate pull down (PD) gate stacks coupled with the semiconductor fin, the one or more PD gate stacks including a PD gate electrode, and one or more multi-gate pass gate (PG) gate stacks coupled with the semiconductor fin, the one or more PG gate stacks including a PG gate electrode, the PG gate electrode having a greater threshold voltage than the PD gate electrode.

### BACKGROUND

Generally, semiconductor devices such as static random access memory (SRAM) require sufficient static noise margin to maintain cell stability during read operations.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1a-1c provide a top-down schematic of making independent gate electrodes for multi-gate transistors, according to but one embodiment;

FIGS. 2a-2g provide a cross-sectional side view schematic of independent gate electrodes for multi-gate transistors, according to but one embodiment;

FIG. 3 is a flow diagram of a method for making independent gate electrodes in multi-gate transistors, according to but one embodiment; and

FIG. 4 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of independent gate electrodes for multi-gate transistors are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

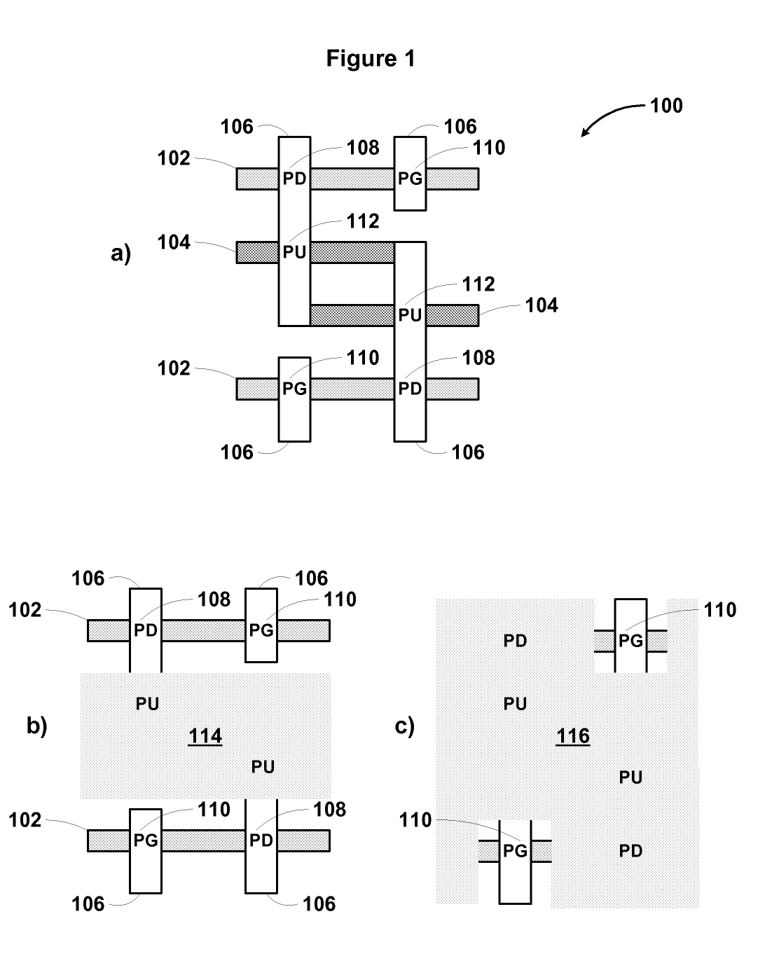

FIGS. 1a-1c provide a top-down schematic of making independent gate electrodes for multi-gate transistors. In an embodiment according to FIG. 1a, an apparatus 100 includes n-diffusion material 102, p-diffusion material 104, gate electrodes 106, pull down (PD) structures or devices 108, pass gate (PG) structures or devices 110, and pull up (PU) structures or devices 112, each coupled as shown. The particular design layout illustrated in FIG. 1a is merely one embodiment of many that fall within the scope and spirit of this description. Other embodiments include more or less transistor devices 108, 110, 112 and/or different arrangements, for example.

Non-planar transistors 108, 110, 112, such as tri-gate transistors, may generally provide exceptional short channel effect control, providing a viable option to support future technology scaling in the semiconductor industry. To enable the use of multi-gate non-planar transistors 108, 110, 112, an on-die memory cache may include tri-gate based six-transistor (6T) SRAM cells 100, according to but one embodiment. A tri-gate based SRAM cell 100 may require sufficient read stability to support array functionality. In an embodiment, SRAM cell read stability is dependent upon static noise margin (SNM), which is strongly dependent upon the conductivity ratio of the PD 108 to PG 110 transistor. This ratio may be called the beta (β) ratio as defined in equation (1) below, where Z_{PD} is the total perimeter of the PD device, L_{PD} is the actual gate length of the PD device, Z_{PG} is the total perimeter of the PG device, and L_{PG} is the actual gate length of the PG device:

β=(Z_{PD}/L_{PD})/(Z_{PG}/L_{PG}) (1)

For example, Z_{PD} or Z_{PG} may be twice the height of the semiconductor fin 102 plus the width of the fin in a u-shaped tri-gate device 108, 110 in an embodiment. In traditional 6T SRAM cells, based on planar transistors, the β ratio may be modulated using transistor sizing to achieve desired cell read stability. However, non-planar transistors 108, 110, 112 such as tri-gate transistors may not be amenable to biasing Z_{PD}, L_{PD}, Z_{PG}, or L_{PG} relative to each other due to drastically different device physics in non-planar transistors. Modulating the β ratio in non-planar transistors 108, 110, 112 such as tri-gate may degrade cell performance and increase short channel effects, for example. In an embodiment, 6T SRAM cells based upon tri-gate transistors require similar sizing between PD 108 and PG 110 devices resulting in near unity or unity β ratio.

In an embodiment, independent gate electrodes are used for the PD 108 and PG 110 transistors to increase static noise margin and cell read stability. Independent gate electrodes may be formed using various techniques. According to one embodiment depicted in FIG. 1a, a gate dielectric such as an oxide is formed on one or more semiconductor fins 102, 104. The one or more semiconductor fins 102, 104 may include one or more silicon pillar structures for forming multi-gate devices. A p-type metal-oxide-semiconductor (PMOS) gate stack 106 may initially be formed on n-diffusion regions 102 and p-diffusion regions 104. In an embodiment, PMOS gate stack 106 is formed across an entire semiconductor wafer. Forming a gate stack 106 may include depositing a gate metal to the gate dielectric and depositing another gate electrode material such as polysilicon to the gate metal.

In an embodiment according to FIG. 1b, a material 114 is applied to p-diffusion regions 104 to prevent removal of PMOS gate stack 106 from the p-diffusion regions 104 while PMOS gate stack 106 materials are removed from the n-diffusion regions 102. In an embodiment, blocking material 114 is a patterned hardmask film. In another embodiment, blocking material 114 includes oxide. An etch process may be used to remove the PMOS gate electrode material from PD 108 and PG 110 devices. In an embodiment an etch process includes a metal etch to remove PMOS gate metal from PD 108 and PG 110 devices.

After removal of PMOS gate stacks from the PD 108 and PG 110 devices, n-type metal-oxide-semiconductor (NMOS) gate stacks 106 may be formed on the n-diffusion 102. Such formation of NMOS gate stacks 106 may form an NMOS gate stack for PD devices 108 as the NMOS gate stack may be removed from the PG devices 108 in FIG. 1c. Hardmask 114 may be removed prior to forming NMOS gate stacks 106 in FIG. 1b. In an embodiment according to FIGS. 1a-b, a dual subtractive etch process flow is used to define NMOS and PMOS gate stacks.

In an embodiment according to FIG. 1c, one or more protective materials 116 are deposited and patterned such that the NMOS PD 108 and PMOS PU 110 gate stacks are protected from removal while the initial NMOS gate stack formed in FIG. 1b is removed from the PG device 110 region. In an embodiment, protective material 116 includes a patterned hardmask film such as oxide. In another embodiment, protective material 116 includes nitride. Other protective materials 116 may be used. The initial PG 110 NMOS gate stack may be removed by an etch process.

In an embodiment, FIG. 1c depicts a replacement metal gate process that results in independent gate stacks for the PG 110 and PD 108 transistors. After removal of protective material 116, a second NMOS gate stack may be formed for PG devices 110. Protective material 116 may not be needed to prevent second NMOS gate stack materials from being deposited on PD 108 and PU 112 devices as the gate stacks have already been formed for the PD 108 and PU 112 devices. The second NMOS gate stack materials may be deposited upon the gate stacks for the PD 108 and PU 112 devices and may be later removed by etching or planarization, for example.

The second PG 110 NMOS gate stack may have a greater threshold voltage than the PD 108 NMOS gate stack to increase static noise margin and read stability in a memory application. In an embodiment, a workfunction metal is selected for a gate metal in the second PG 110 NMOS gate stack such that the threshold voltage in the PG 110 device is greater than the PD 108 device. In an embodiment, augmenting the PG device 110 threshold voltage relative to the PD 108 device creates “effective” change in beta ratio in an SRAM cell, resulting in an increase in static noise margin.

In an embodiment, an apparatus 100 includes a semiconductor fin 102, one or more multi-gate PD devices 108 having one or more PD 108 gate stacks coupled with the semiconductor fin 102, the one or more PD 108 gate stacks having a PD 108 gate metal, and one or more multi-gate PG 110 devices having one or more PG 110 gate stacks coupled with the semiconductor fin 102, the one or more PG 110 gate stacks having a PG 110 gate metal where the PG 110 gate metal has a greater threshold voltage than the PD 108 gate metal. In an embodiment, PD 108 and PG 110 devices include NMOS gate stacks while PU 112 devices include PMOS gate stacks.

In an embodiment, the semiconductor fin 102 and the one or more PD 108 and PG 110 devices are part of a static random access memory (SRAM) cell having a β that is about equal to one. In another embodiment, the one or more PD devices 108 are tri-gate PD devices and the one or more PG devices 108 are tri-gate PG devices. The PD 108 and/or PG devices may be u-shaped tri-gate transistors. In an embodiment, the semiconductor fin 102 and the one or more PD 108 and PG 110 devices are part of a 6T cell, the 6T cell including two PD devices 108, two PG devices 110 and two pull-up (PU) devices 112.

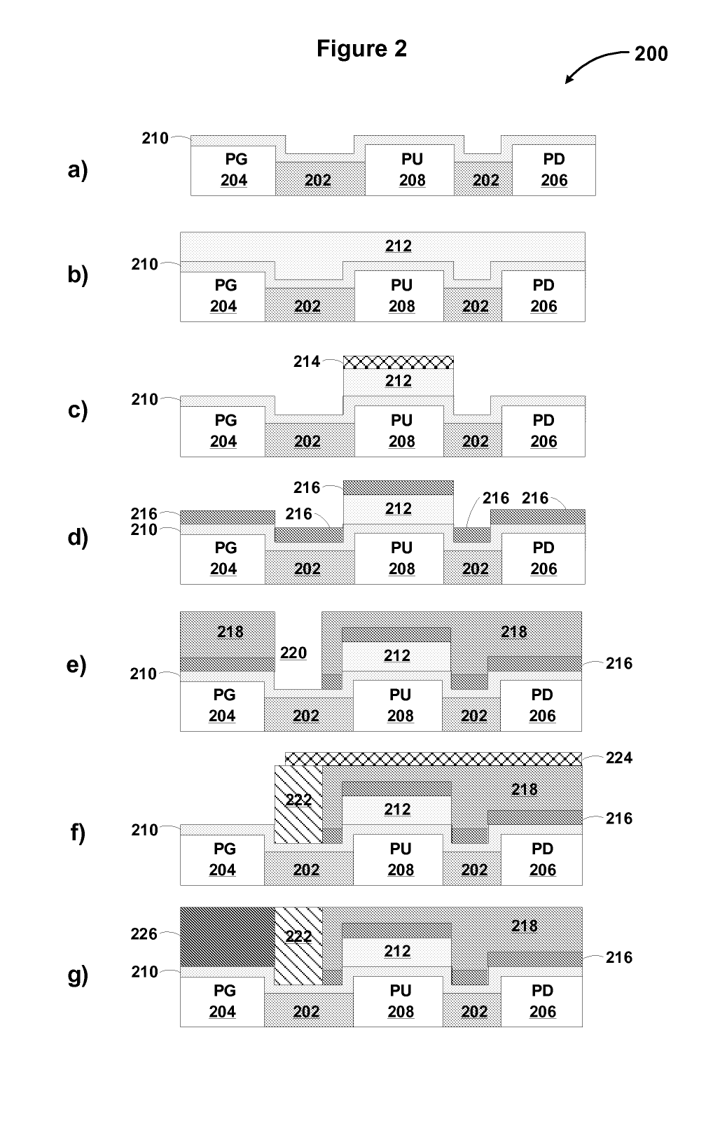

FIGS. 2a-2g provide a cross-sectional side view schematic of independent gate electrodes for multi-gate transistors, according to but one embodiment. In an embodiment according to FIG. 2a, an apparatus 200 includes a dielectric material such as shallow-trench isolation (STI) 202, PG semiconductor structure 204, PD semiconductor structure 206, PU semiconductor structure 208, and gate dielectric 210, each coupled as shown.

PG 204, PD 206, and PU 208 semiconductor structures may include semiconductor fins and/or pillars formed in a semiconductor substrate such as silicon, germanium, any other suitable semiconductor material, or combinations thereof PG 204 and PD 206 structures may include n-type semiconductor material and PU 208 structure may include p-type material. STI material 202 may be slightly recessed to allow the formation of multi-gate transistors using the top and sidewalls of the PG 204, PD 206, and PU 208 structures to form tri-gate devices, according to but one embodiment. Gate dielectric 210 may include high-k dielectric materials including oxide or nitride materials, for example.

In an embodiment according to FIG. 2b, an apparatus 200 includes a dielectric material such as shallow-trench isolation (STI) 202, PG semiconductor structure 204, PD semiconductor structure 206, PU semiconductor structure 208, gate dielectric 210, and PU gate metal 212, each coupled as shown. FIG. 2b may be a depiction of FIG. 2a after deposition of a PU gate metal 212 to the gate oxide 210. PU gate metal 212 may be a PMOS metal. In an embodiment, PU gate metal 212 is deposited to cover the PG 204, PD 206, and PU 208 regions. PU gate metal 212 may be deposited by a blanket deposition to a wafer including PG 204, PD 206, and PU 208 structures.

In an embodiment according to FIG. 2c, an apparatus 200 includes a dielectric material such as shallow-trench isolation (STI) 202, PG semiconductor structure 204, PD semiconductor structure 206, PU semiconductor structure 208, gate dielectric 210, PU gate metal 212, and hardmask 214, each coupled as shown. FIG. 2c may be a depiction of FIG. 2b after hardmask 214 has been deposited to prevent removal of PU gate metal 212 from the PU structure 208 region and after PU gate metal 212 material has been selectively removed from the PG 204 and PD 206 structures. FIG. 2c may depict an apparatus 200 similar to an apparatus 100 according to FIG. 1b after a removal process such as a dual subtractive etch removes PMOS gate metal 212 from the PD 204 and PG 206 structures in preparation for NMOS gate metal 216 to be deposited to the PG 204 and PD 206 structures.

In an embodiment, hardmask 214 protects PU gate metal 212 from an etch process that removes PU gate metal 212 from the PD 204 and PG 206 structures. Other suitable forms of patterning and/or forming PU gate metal 212 as depicted may be used in other embodiments.

In an embodiment according to FIG. 2d, an apparatus 200 includes a dielectric material such as shallow-trench isolation (STI) 202, PG semiconductor structure 204, PD semiconductor structure 206, PU semiconductor structure 208, gate dielectric 210, PU gate metal 212, and PD gate metal 216, each coupled as shown. FIG. 2d may be a depiction of FIG. 2c after hardmask 214 has been removed and PD gate metal 216 has been deposited. In an embodiment, PD gate metal 216 is an NMOS metal deposited by blanket deposition.

In an embodiment according to FIG. 2e, an apparatus 200 includes a dielectric material such as shallow-trench isolation (STI) 202, PG semiconductor structure 204, PD semiconductor structure 206, PU semiconductor structure 208, gate dielectric 210, PU gate metal 212, PD gate metal 216, and another gate electrode material 218 such as polysilicon, each coupled as shown. FIG. 2e may be a depiction of FIG. 2d after polysilicon 218 has been deposited, polished, and patterned to form one or more openings 220 in the polysilicon 218 and PD gate metal 216 as depicted. Polysilicon 218 and PD gate metal 216 may be removed 220 between the PG structure 204 and PU structure 208 in this cross-section embodiment.

In an embodiment according to FIG. 2f, an apparatus 200 includes a dielectric material such as shallow-trench isolation (STI) 202, PG semiconductor structure 204, PD semiconductor structure 206, PU semiconductor structure 208, gate dielectric 210, PU gate metal 212, PD gate metal 216, another gate electrode material 218 such as polysilicon, protective material 222 such as nitride, and hardmask protective material 224, each coupled as shown. FIG. 2f may be a depiction of FIG. 2e after a protective material 222 such as nitride has been deposited and polished, hardmask protective material 224 has been deposited to prevent removal of polysilicon 218 and PD gate metal 216 from the PU 208 and PD 206 structures, and polysilicon 218 and PD gate metal 216 has been removed from the PG 204 structures. In an embodiment, FIG. 2f is analogous to FIG. 1c.

In an embodiment, nitride 222 is polished back to the level of the polysilicon 218. In an embodiment, hardmask 224 is a material that prevents removal by etching of polysilicon 218 and/or PD gate metal 216 from covered regions. A new gate stack may be formed for the PG structure 204 in the region where PD gate metal 216 was removed to provide independent gate electrodes for the PG structure 204 and the PD structure 206.

In an embodiment according to FIG. 2g, an apparatus 200 includes a dielectric material such as shallow-trench isolation (STI) 202, PG semiconductor structure 204, PD semiconductor structure 206, PU semiconductor structure 208, gate dielectric 210, PU gate metal 212, PD gate metal 216, another gate electrode material 218 such as polysilicon, protective material such as nitride 222, and PG gate metal 226, each coupled as shown. FIG. 2g may be a depiction of FIG. 2f after removal of hardmask 224 and deposition of PG gate metal 226. In an embodiment, PG gate metal 226 is deposited by blanket deposition and then polished back to the level of the nitride 222. In an embodiment, the nitride 222 is removed after polishing the PG gate metal 226. PG gate metal 226 may have a thickness selected to provide a threshold voltage relative to the PD gate metal 216 according embodiments disclosed herein. Additional gate electrode material such as polysilicon 218 may be deposited to form a gate stack for the PG structure 204.

In an embodiment, a gate electrode includes gate metal 212, 216, 226 and/or electrically conductive materials such as polysilicon 218 coupled with the device structures 204, 206, 208 through gate dielectric 210. In other embodiments, the order of PG 226 and PD 216 gate metal deposition is reversed such that a PG gate metal 226 is deposited prior to a PD gate metal 216, using similar or analogous methods to those already disclosed.

In an embodiment, an apparatus 200 includes a semiconductor fin 204, 206, one or more multi-gate PD devices having one or more PD gate stacks 210, 216, 218 coupled with the semiconductor fin 206, the one or more PD gate stacks 210, 216, 218 including a PD gate electrode 216, and one or more multi-gate PG devices having one or more PG gate stacks 210, 226, 218 coupled with the semiconductor fin 204, the one or more PG gate stacks 210, 226, 218, including a PG gate electrode 226, the PG gate electrode 226 having a greater threshold voltage than the PD gate electrode 216.

In an embodiment, the PD gate electrode 216 and the PG gate electrode 226 are workfunction metals, the PD gate workfunction metal 216 being different than the PG gate workfunction metal 226 such that the PG gate workfunction metal 226 has a higher threshold voltage than the PD gate workfunction metal 216. Such characteristic may result in a higher threshold voltage for the PG device relative to the PD device to increase static noise margin and read stability in a memory application, for example.

In another embodiment, the thickness of the PG gate electrode 226 is greater than the thickness of the PD gate electrode 216 resulting in a higher threshold voltage for the PG device relative to the PD device. For example, the PG gate electrode 226 material and the PD gate electrode 216 material may be the same material, but modulating the thickness as described above may result in a different threshold voltage for the PG and PD devices.

A gate dielectric 210 may be coupled to the semiconductor fin 204, 206 and a PD gate stack including a PD gate electrode 216 coupled with a first polysilicon structure 218 may be coupled to the gate dielectric 210 via the PD gate electrode 216. A PG gate stack including a PG gate electrode 226 coupled with a second polysilicon structure (not shown) may be coupled to the gate dielectric 210 via the PG gate electrode 226. A second polysilicon structure may be an additional polysilicon structure coupled with PG gate electrode 226 after processing in FIG. 2g.

In an embodiment, the semiconductor fin 204, 206 and the one or more PD and PG devices are part of an SRAM cell having a P that is about equal to one. In another embodiment, the one or more PD devices are tri-gate PD devices and the one or more PG devices are tri-gate PG devices. The one or more PD and PG devices may be part of a six-transistor cell, the six-transistor cell having two PD devices, two PG devices and two pull-up (PU) devices.

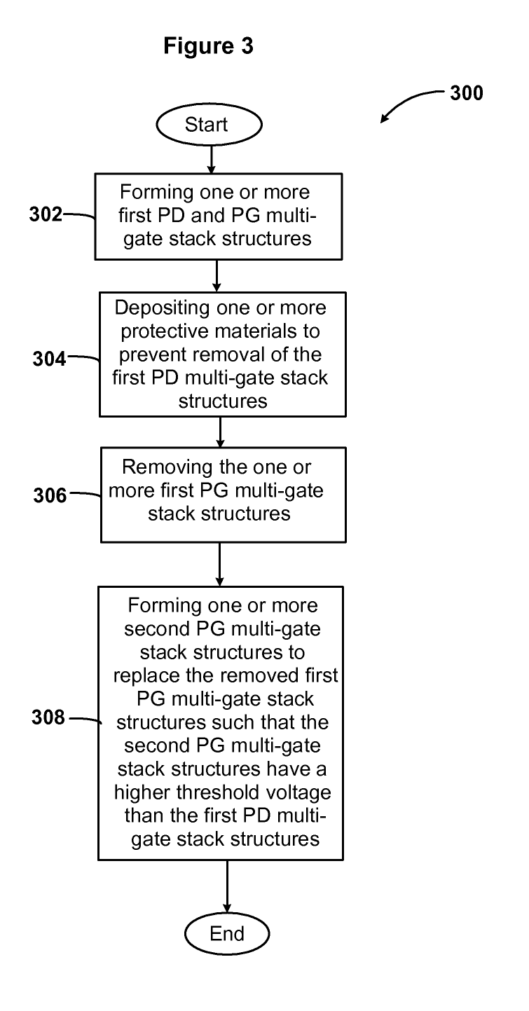

FIG. 3 is a flow diagram of a method for making independent gate electrodes in multi-gate transistors, according to but one embodiment. In an embodiment, a method 300 includes forming one or more first PD and PG multi-gate stack structures at box 302, depositing one or more protective materials to prevent removal of the first PD multi-gate stack structures at box 304, removing the one or more first PG multi-gate stack structures at box 306, and forming one or more second PG multi-gate stack structures to replace the removed first PG multi-gate stack structures such that the second PG multi-gate stack structures have a higher threshold voltage than the first PD multi-gate stack structures at box 308, with arrows providing but one suggested flow.

In an embodiment, the first PD and PG multi-gate stack structures include at least a first gate metal coupled to a gate dielectric. Forming one or more first PD and PG multi-gate stack structures 302 may include depositing the gate dielectric to one or more semiconductor fins, depositing the first gate metal to the gate dielectric, and depositing a first polysilicon to the first gate metal.

Depositing one or more protective materials 304 may include depositing a nitride material into regions disposed between the one or more first PD and PG multi-gate structures. In another embodiment, depositing one or more protective materials 304 includes depositing a hardmask protective material to cover at least the PD multi-gate stack structures. The protective materials 304 may prevent removal of the first PD multi-gate stack structures while the first PG multi-gate stack structures are removed 306. Removing the one or more first PG multi-gate stack structures 306 may be accomplished by etching, for example. In an embodiment, a method 300 further includes removing the one or more protective materials.

Forming one or more second PG multi-gate stack structures 308 may include depositing a second gate metal to the gate dielectric wherein the second gate metal has a higher threshold voltage than the first gate metal used in forming the one or more first PD and PG multi-gate stack structures 302. In an embodiment, forming one or more second PG multi-gate stack structures 308 further includes depositing a polysilicon structure to the second gate metal.

In another embodiment, forming one or more second PG multi-gate stack structures 308 includes depositing a second gate metal to the gate dielectric, wherein the second gate metal is the same type of metal as the first metal used in forming the one or more first PD and PG multi-gate stack structures 302, resulting in a higher threshold voltage in the second PG multi-gate stack structure than the first PD and PG multi-gate stack structures. Such difference in threshold may increase static noise margin and read stability in a memory device, for example. Forming one or more second PG multi-gate stack structures 308 may further include depositing a polysilicon structure to the second gate metal. Forming one or more second PG multi-gate stack structures to replace the removed first PG multi-gate stack structures 308 may be part of forming a 6T SRAM cell having a β that is about equal to one.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

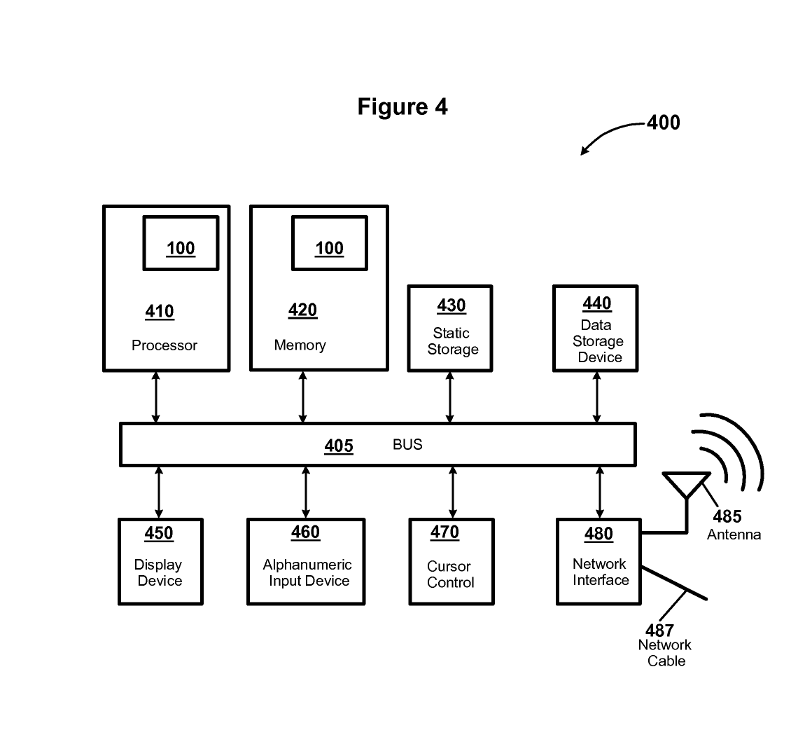

FIG. 4 is a diagram of an example system in which embodiments of the present invention may be used, according to but one embodiment. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 400 includes an apparatus having independent gate electrodes for multi-gate transistors 100 in accordance with embodiments described with respect to FIGS. 1-3. In an embodiment, an apparatus having independent gate electrodes for multi-gate transistors 100 as described herein is part of an electronic system's processor 410 or memory 420.

Electronic system 400 may include bus 405 or other communication device to communicate information, and processor 410 coupled to bus 405 that may process information. While electronic system 400 may be illustrated with a single processor, system 400 may include multiple processors and/or co-processors. In an embodiment, processor 410 includes an apparatus having independent gate electrodes for multi-gate transistors 100 in accordance with embodiments described herein. System 400 may also include random access memory (RAM) or other storage device 420 (may be referred to as memory), coupled to bus 405 and may store information and instructions that may be executed by processor 410.

Memory 420 may also be used to store temporary variables or other intermediate information during execution of instructions by processor 410. Memory 420 is a flash memory device in one embodiment. In another embodiment, memory 420 includes an apparatus having independent gate electrodes for multi-gate transistors 100 as described herein.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one or more omnidirectional antennae 485, which may refer to an antenna that is at least partially omnidirectional and/or substantially omnidirectional, and a processor 410 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a semiconductor fin;
one or more multi-gate pull down (PD) gate stacks coupled with the semiconductor fin, the one or more PD gate stacks comprising a PD gate electrode; and
one or more multi-gate pass gate (PG) gate stacks coupled with the semiconductor fin, the one or more PG gate stacks comprising a PG gate electrode, the PG gate electrode having a greater threshold voltage than the PD gate electrode.

2. An apparatus according to claim 1 wherein the semiconductor fin and the one or more multi-gate PD and PG gate stacks are part of a static random access memory (SRAM) cell having a β that is about equal to one, β being defined as follows, where Z_{PD} is the total perimeter of a PD device, L_{PD} is an actual gate length of the PD device, Z_{PG} is the total perimeter of a PG device, and L_{PG} is an actual gate length of the PG device:
β=(Z_{PD}/L_{PD})/(Z_{PG}/L_{PG}).

3. An apparatus according to claim 1 wherein the PD and PG gate electrodes comprise workfunction metals, the PD gate workfunction metal being different than the PG gate workfunction metal such that the PG gate workfunction metal has a higher threshold voltage than the PD gate workfunction metal resulting in a higher threshold voltage for a PG device having the PG gate workfunction metal relative to a PD device having the PD gate workfunction metal to increase static noise margin and read stability in a memory application.

4. An apparatus according to claim 1 wherein the thickness of the PG gate electrode is greater than the thickness of the PD gate electrode resulting in a higher threshold voltage for a PG device having the PG gate electrode relative to a PD device having the PD gate electrode to increase static noise margin and read stability in a memory application.

5. An apparatus according to claim 1 further comprising:
a gate dielectric coupled to the semiconductor fin wherein the PD and PG gate stacks are coupled to the gate dielectric via the respective PD and PG gate electrodes, the PD gate stack comprising the PD gate electrode coupled with a first polysilicon structure, the PG gate stack comprising the PG gate electrode coupled with a second polysilicon structure.

6. An apparatus according to claim 1 wherein the one or more PD gate stacks form tri-gate PD devices and wherein the one or more PG gate stacks form tri-gate PG devices.

7. An apparatus according to claim 1 wherein the one or more PD and PG gate stacks are part of a six-transistor cell, the six-transistor cell comprising two PD devices, two PG devices and two pull-up (PU) devices.

8. A method comprising:
forming one or more first pull down (PD) and pass gate (PG) multi-gate stack structures, the PD and PG multi-gate structures comprising at least a first gate metal coupled to a gate dielectric;
depositing one or more protective materials to prevent removal of the one or more first PD multi-gate stack structures;
removing the one or more first PG multi-gate stack structures; and
forming one or more second PG multi-gate stack structures to replace the removed first PG multi-gate stack structures such that the second PG multi-gate stack structures have a higher threshold voltage than the first PD multi-gate stack structures.

9. A method according to claim 8 wherein forming one or more first PD and PG multi-gate stack structures comprises:
depositing the gate dielectric to one or more semiconductor fins;
depositing the first gate metal to the gate dielectric; and
depositing a first polysilicon to the first gate metal.

10. A method according to claim 8 wherein depositing one or more protective materials comprises:
depositing a nitride material into regions disposed between the one or more first PD and PG multi-gate stack structures; and
depositing a hardmask protective material to cover at least the PD multi-gate stack structures.

11. A method according to claim 8 wherein removing the one or more first PG multi-gate stack structures comprises etching the first PG multi-gate stack structures.

12. A method according to claim 8 wherein forming one or more second PG multi-gate stack structures comprises:
depositing a second gate metal to the gate dielectric, wherein the second gate metal has a higher threshold voltage than the first gate metal used in forming the one or more first PD and PG multi-gate stack structures to increase static noise margin and read stability in a memory application; and
depositing a polysilicon structure to the second gate metal.

13. A method according to claim 8 wherein forming one or more second PG multi-gate stack structures comprises:
depositing a second gate metal to the gate dielectric, wherein the second gate metal is the same type of metal as the first metal used in forming the one or more first PD and PG multi-gate stack structures and wherein the thickness of the second gate metal is greater than the thickness of the first gate metal resulting in a higher threshold voltage in the second PG multi-gate stack structure than the first PD and PG multi-gate stack structures to increase static noise margin and read stability in a memory application; and
depositing a polysilicon structure to the second gate metal.

14. A method according to claim 8 further comprising:
removing the one or more protective materials.

15. A method according to claim 8 wherein forming one or more second PG multi-gate stack structures to replace the removed first PG multi-gate stack structures is part of forming a six-transistor static random access memory (SRAM) cell having a β that is about equal to one, β being defined as follows, where Z_{PD} is the total perimeter of the PD device, L_{PD} is an actual gate length of the PD device, Z_{PG} is the total perimeter of the PG device, and L_{PG} is an actual gate length of the PG device:
β=(Z_{PD}/L_{PD})/(Z_{PG}/L_{PG}).
